(19) United States
(12) Patent Application Publication
(10) Pub. No.: US 2004/0126918 A1
(43) Pub. Date: Jul. 1, 2004

(54) Semiconductor light emitting device and method for manufacturing same

(75) Inventors: Takahisa Kurahashi, Kashiba-shi (JP); Hiroshi Nakatsu, Mihara-shi (JP); Tetsurou Murakami, Tenri-shi (JP); Shouichi Ooyama, Nara-ken (JP)

Correspondence Address: Barry E. Bretschneider, Morrison & Foerster LLP, Suite 300, 1650 Tysons Boulevard, McLean, VA, 22102, US

(73) Assignee: SHARP KABUSHIKI KAISHA, Osaka (JP)

(21) Appl. No.: 10/684,127

(22) Filed: Oct. 14, 2003

(30) Foreign Application Priority Data
Oct. 11, 2002 (JP) P2002-299244
Aug. 12, 2003 (JP) P2003-292127

(51) Int. Cl. H01L 21/00; H01L 33/00

(52) U.S. Cl. 438/47; 438/29; 438/22; 257/98; 257/91

(57) ABSTRACT

A light emitting layer 4 composed of a single or a plurality of semiconductor layers is laminated on a nondope type, weak p-type, or n-type first semiconductor substrate (not shown in FIG. 1). On the light emitting layer 4, n-type semiconductor layers 5-7 composed of a single layer or a plurality of layers are laminated. On the surface of the n-type semiconductor layer 7, a second semiconductor substrate 8 transparent to the wavelength of emitted light from the light emitting layer 4 is formed. Then, the first semiconductor substrate is removed. On the plane exposed by removal of the first semiconductor substrate, a translucent electrode layer 9 transparent to the wavelength of emitted light from the light emitting layer is formed.

### BACKGROUND OF THE INVENTION

The present invention relates to a semiconductor light emitting device and a method for manufacturing the same.

In recent years, in the filed of semiconductor light emitting devices, light emitting diodes (LEDs) have widely been used in optical communications, LED information display panels or the like. It is important for these light emitting diodes to have high luminance, and the luminance of the light emitting diodes, i.e., external quantum efficiency, is determined by internal quantum efficiency and light extraction efficiency, among which the light extraction efficiency is significantly influenced by element structure.

In the light emitting diodes, substrates transparent to the wavelength of emitted light are used for increasing the light extraction efficiency. This is because use of substrates opaque to the wavelength of light enables only a ray of light emitted to the upper face to be extracted, whereas use of the substrates transparent to the wavelength of emitted light enables rays of light to be extracted not only from the upper face but also from four side faces. Further, a ray of light reflected on the lower face can also exit from the upper face and the side faces. This method is applied to infrared light emitting diodes composed of InGaAsP based semiconductor materials, red and infrared light emitting diodes composed of AlGaAs based semiconductor materials, yellow light emitting diodes composed of GaAsP based semiconductor materials, green light emitting diodes composed of GaP based semiconductor materials and the like.

As a manufacturing method for manufacturing an AlGaInP based light emitting diode having a substrate transparent to the wavelength of emitted light, there is known a method made up of the steps of epitaxially growing, as shown in FIG. 10A, an n-type semiconductor layer 112, a light emitting layer 114, and a p-type semiconductor layer 116 on an n-type GaAs substrate 110 that is opaque to the wavelength of emitted light, carrying out heat treatment with a p-type GaP substrate 120 that is transparent to the wavelength of emitted light being placed on the p-type semiconductor layer 116 for establishing direct bonding between the p-type GaP substrate 120 and the p-type semiconductor layer 116, and then, as shown in FIG. 10B, removing the n-type GaAs substrate 110 (see Specification of Japanese Patent No. 3230638).

Also, there is known another manufacturing method made up of the steps of epitaxially growing, as shown in FIG. 11A, an n-type semiconductor layer 212, a light emitting layer 214, a p-type semiconductor layer 216, and a p-type GaP current diffusion layer 218 with a thickness of approximately 50 μm to 100 μm on an n-type GaAs substrate 210 that is opaque to the wavelength of emitted light, removing the n-type GaAs substrate 210 as shown in FIG. 11B, and then, as shown in FIG. 11C, carrying out heat treatment with a n-type GaP substrate 220 being placed on the plane exposed by the removing step for establishing direct bonding between the n-type semiconductor layer 212 and the n-type GaP substrate 220 (see Japanese Patent Laid-Open Publication HEI 6-302857). It is noted that the p-type GaP current diffusion layer 218, if its thickness is 50 μm or less, tends to cause breakage when handled as a wafer, whereas if its thickness is 100 μm or more, a growth duration of time becomes longer, thereby making manufacturing costs of the light emitting diode higher. Therefore, in consideration of the growth duration of time and mechanical strength of a wafer after removal of the GaAs substrate, the thickness of the p-type GaP current diffusion layer 218 is set to approximately 50 μm to 100 μm.

There is known still another manufacturing method made up of the steps of epitaxially growing, as shown in FIG. 12A, a p-type GaAs buffer layer 311, a p-type AlGaAs current diffusion layer 312, a p-type cladding layer 313, an active layer 314, an n-type cladding layer, an n-type intermediate layer 316, and an n-type GaP layer 317 on an n-type GaAs substrate 310 opaque to the wavelength of emitted light, forming an n-type GaP substrate 318 thereon as shown in FIG. 12B, and then removing the n-type GaAs substrate 310 (see Japanese Patent Laid-Open Publication No. 2000-196139).

However, the above-mentioned methods pose a problem that the total volume of p-type dopants such as Zn and Mg contained in the p-type substrates 120, 220 and the p-type current diffusion layers 218, 312 in the vicinity of the light emitting layer (or the active layer) is large, so that thermal history in crystal growing or in direct bonding operation causes the p-type dopants to diffuse into the light emitting layer (or the active layer), resulting in decreased internal quantum efficiency and decreased luminance of the device. Particularly, in the AlGaInP based light emitting diodes that lattice-match with GaAs substrates and that may implement small resistivity, there is used AlₓGa₁₋ₓAs (0.5≦×≦1), which is the only one known material that is transparent to the wavelength of emitted light. In the AlₓGa₁₋ₓAs (0.5≦×≦1), diffusion coefficients of Zn, Mg and the like are large, which aggravates the problem.

Moreover, the p-type current diffusion layers 218, 312 are usually grown to be several μm or more in thickness as described above while other layers are grown to be several μm or less in thickness, which poses a problem of increased maintenance frequency of growth equipment and decreased productivity. Since maintenance operation involves generation of poisonous gases, smaller maintenance frequency is preferable also from the viewpoint of safety.

### SUMMARY OF THE INVENTION

It is a primary object of the present invention to provide a semiconductor light emitting device capable of restraining diffusion of p-type dopants into the light emitting layer (or the active layer) for implementing high luminance and capable of decreasing maintenance frequency of growth equipment, and to provide a method for manufacturing the same.

In order to accomplish the above object, there is provided a method for manufacturing a semiconductor light emitting device of the present invention, comprising:

laminating a light emitting layer on a nondope type, weak p-type, or n-type first semiconductor substrate, the light emitting layer being composed of a single or a plurality of semiconductor layers;

laminating an n-type semiconductor layer on the light emitting layer, the n-type semiconductor layer being composed of a single or a plurality of layers;

forming a second semiconductor substrate on an surface of the n-type semiconductor layer, the second semiconductor substrate being transparent to a wavelength of emitted light from the light emitting layer;

then removing the first semiconductor substrate; and

forming a translucent electrode layer on a plane exposed by removing of the first semiconductor substrate, the translucent electrode layer being transparent to the wavelength of emitted light from the light emitting layer.

It is noted that a phrase “weak p-type” of the first semiconductor substrate refers to the level of a p-type which makes the diffusion of the p-type dopants into the light emitting layer (or the active layer) substantially negligible.

According to the method for manufacturing the semiconductor light emitting device of the present invention, there is manufactured a semiconductor light emitting device comprises a translucent electrode layer and a second semiconductor substrate disposed above and below the light emitting layer respectively, both of which are transparent to the wavelength of emitted light from the light emitting layer. This makes it possible to extract light from the upper face and side faces of the device, which increases light extraction efficiency compared to the case of using a substrate opaque to the wavelength of emitted light. Moreover, since no p-type substrate nor p-type current diffusion layer is provided in the vicinity of the light emitting layer, p-type dopants are restrained from diffusing into the light emitting layer during high-temperature treatment. Furthermore, the translucent electrode layer is formed on the plane exposed by removal of the first semiconductor substrate, so that a passing current is diffused by the translucent electrode layer during operation, and evenly injected into the light emitting layer. Consequently, the internal quantum efficiency is increased. As a result, the property of the semiconductor light emitting device is improved and high luminance is implemented. Also in the method for manufacturing the semiconductor light emitting device of the present invention, the current diffusion layer is not provided, which may reduce the thickness of epitaxially grown layers. Therefore, it becomes possible to decrease maintenance frequency of the growth equipment, resulting in increased productivity as well as enhanced safety.

In one embodiment, the method for manufacturing the semiconductor light emitting device further comprises, before laminating the light emitting layer on the first semiconductor substrate, forming a p-type semiconductor layer on the first semiconductor substrate, wherein the p-type semiconductor layer is composed of a single layer or a plurality of layers whose composition is different from that of the first semiconductor substrate.

More specifically, the method for manufacturing the semiconductor light emitting device in this one embodiment comprises the steps of:

forming a p-type semiconductor layer on a nondope-type, weak p-type, or n-type first semiconductor substrate, the p-type semiconductor layer being composed of a single layer or a plurality of layers whose composition is different from that of the first semiconductor substrate;

laminating a light emitting layer on the p-type semiconductor layer, the light emitting layer being composed of a single or a plurality of semiconductor layers;

laminating an n-type semiconductor layer on the light emitting layer, the n-type semiconductor layer being composed of a single layer or a plurality of layers;

forming a second semiconductor substrate on the surface of the n-type semiconductor layer, the second semiconductor substrate being transparent to the wavelength of emitted light from the light emitting layer;

then removing the first semiconductor substrate; and

forming a translucent electrode layer on the plane exposed by removing of the first semiconductor substrate, the translucent electrode layer being transparent to the wavelength of emitted light from the light emitting layer.

According to the method for manufacturing the semiconductor light emitting device in this one embodiment, there is manufactured a semiconductor light emitting device composed of the translucent electrode layer and the second semiconductor substrate disposed above and below the light emitting layer respectively, both of which are transparent to the wavelength of emitted light from the light emitting layer. This makes it possible to extract light from the upper face and side faces of the device, which increases light extraction efficiency compared to the case of using a substrate opaque to the wavelength of emitted light. Moreover, since no p-type substrate is provided in the vicinity of the light emitting layer, p-type dopants are restrained from diffusing into the light emitting layer during high-temperature treatment. Furthermore, the translucent electrode layer is formed on the plane exposed by removal of the first semiconductor substrate, so that a passing current is diffused by the translucent electrode layer during operation and evenly injected into the light emitting layer. Consequently, the internal quantum efficiency is increased. Further, the plane that constitutes the translucent electrode is a plane exposed by removal of the first semiconductor substrate, that is the plane of the p-type semiconductor layer composed of a single layer or a plurality of layers. Therefore, it becomes possible to make voltage drop on a interface between the electrode and the semiconductor smaller than that in the case of directly forming a translucent electrode on the light emitting layer. As a result, the property of the semiconductor light emitting device is improved and high luminance is implemented. Also in the method for manufacturing the semiconductor light emitting device of the present invention, the current diffusion layer is not provided, which may reduce the thickness of epitaxially grown layers. Therefore, it becomes possible to decreased maintenance frequency of the growth equipment, resulting in increased productivity as well as enhanced safety.

The first semiconductor substrate is preferably a GaAs substrate. If the first semiconductor substrate is a GaAs substrate, it becomes possible to manufacture a high-luminance semiconductor light emitting device composed of a semiconductor layer made of materials that lattice-match with the GaAs substrate.

Also, the light emitting layer is preferably composed of (Al_{y}Ga_{1-y})_{z}In_{1-z}P (where 0≦y ≦1, 0≦z≦1). If the light emitting layer is composed of (Al_{y}Ga_{1-y})_{z}In_{1-z}P, it becomes possible to manufacture a high-luminance semiconductor light emitting device that emits light in the wavelength of 550 nm to 670 nm.

Also, the second semiconductor substrate is preferably a GaP substrate. Since GaP is transparent to rays of light in the wavelength over 550 nm, the second semiconductor substrate being a GaP substrate makes it possible to increase light extraction efficiency.

Also, the translucent electrode layer is preferably composed of at least one of indium oxide, tin oxide, indium tin oxide, zinc oxide, and magnesium oxide. If the translucent electrode layer is composed of at least one of indium oxide, tin oxide, indium tin oxide, zinc oxide, and magnesium oxide, it becomes possible to obtain 90% or more transmittance of visible light. Therefore, it further ensures implementation of high luminance.

In one embodiment of the method for manufacturing the semiconductor light emitting device, the second semiconductor substrate is formed through direct bonding.

In the method for manufacturing the semiconductor light emitting device in this one embodiment, the second semiconductor substrate is formed through direct bonding, which enables the thickness of the second semiconductor substrate to be easily set to the level sufficient in terms of mechanical strength.

In one embodiment of the method for manufacturing the semiconductor light emitting device, the second semiconductor substrate is formed through epitaxial growing.

In the method for manufacturing the semiconductor light emitting device in this one embodiment, the second semiconductor substrate is formed through epitaxial growing, which enables the second semiconductor substrate to be easily grown to a target thickness, thereby eliminating the necessity of providing an additional step such as polishing of the second semiconductor substrate. Therefore, compared to the case of providing the second semiconductor substrate through direct bonding, it becomes possible to simplify the manufacturing process of the semiconductor light emitting device.

In one embodiment of the method for manufacturing the semiconductor light emitting device, the p-type semiconductor layer has a carrier density of 1×10¹⁸cm⁻³ or more and 1×10¹⁹cm⁻³ or less, and contains an AlₓGa₁₋ₓAs layer (where 0.5≦×≦0.7) that is transparent to the wavelength of emitted light from the light emitting layer.

According to the method for manufacturing the semiconductor light emitting device in this one embodiment, the p-type semiconductor layer has a carrier density of 1×10¹⁸cm⁻³ or more, so that it becomes possible to decrease voltage drop occurred during operation of the device on a interface between the translucent electrode layer and the p-type semiconductor layer, resulting in reduction of operating voltage of the device. It is noted that the p-type semiconductor layer is an AlₓGa₁₋ₓAs layer (where 0.5≦×≦0.7) that is transparent to the wavelength of emitted light from the light emitting layer, which contributes to prevention of light extraction efficiency from decreasing. Moreover, the p-type semiconductor layer is given an upper limit of the carrier density, that is 1×10¹⁹cm⁻³ or less. Eventually, limiting the thickness of the p-type semiconductor layer to be within a specified value leads to restriction of the total volume of p-type dopants, which makes it possible to restrain the p-type dopants from diffusing into the light emitting layer during high-temperature treatment. Therefore, depression of the internal quantum efficiency may be inhibited. As a result, decrease in luminance of the semiconductor light emitting device may be prevented.

In one embodiment of the method for manufacturing the semiconductor light emitting device, the p-type semiconductor layer has a carrier density of 1×10¹⁸cm⁻³ or more and 1×10¹⁹cm⁻³ or less, and contains an (Al_{y}Ga_{1-y})_{z}In_{1-z}P layer (where 0≦y≦1, 0≦z≦1) that is transparent to the wavelength of emitted light from the light emitting layer.

According to the method for manufacturing the semiconductor light emitting device in this one embodiment, the p-type semiconductor layer has a carrier density of 1×10¹⁸cm⁻³ or more, so that it becomes possible to decrease voltage drop on a interface between the translucent electrode layer and the p-type semiconductor layer occurred during operation of the device, resulting in reduction of operating voltage of the device. It is noted that the p-type semiconductor layer is an (Al_{y}Ga_{1-y})_{z}In_{1-z}P layer (where 0≦y≦1, 0≦z≦1) that is transparent to the wavelength of emitted light from the light emitting layer, which contributes to prevention of light extraction efficiency from decreasing. Moreover, the p-type semiconductor layer is given an upper limit of the carrier density, that is 1×10¹⁹cm⁻³ or less. Eventually, limiting the thickness of the p-type semiconductor layer to be within a specified value leads to restriction of the total volume of p-type dopants, which makes it possible to restrain the p-type dopants from diffusing into the light emitting layer during high-temperature treatment. This inhibits depression of the internal quantum efficiency. As a result, decrease in luminance of the semiconductor light emitting device may be prevented. Further, it becomes possible to set an Al composition ratio x smaller than that in the case of using AlₓGa₁₋ₓAs (where 0.5≦×≦0.7) as a material of the p-type semiconductor layer. Thus, with the smaller Al composition ratio x, the surface becomes resistant to oxidizing, which makes it possible to decrease voltage drop on a interface between the translucent electrode layer and the p-type semiconductor layer, thereby achieving an increased yield of the device.

In one embodiment of the method for manufacturing the semiconductor light emitting device, the p-type semiconductor layer has a thickness of 3 μm or less.

In the method for manufacturing the semiconductor light emitting device in this one embodiment, the total volume of p-type dopants such as Zn and Mg in the p-type semiconductor layer is restricted, so that diffusion of the p-type dopants into the light emitting layer during high-temperature treatment is restrained. This inhibits depression of the internal quantum efficiency. As a result, decrease in luminance of the semiconductor light emitting device may be prevented.

There is provided a semiconductor light emitting device of the present invention, comprising

a light emitting layer composed of a single layer or a plurality of layers and a translucent electrode layer laminated in this order on one face of a GaP substrate, the GaP substrate and the translucent electrode layer being transparent to a wavelength of emitted light from the light emitting layer,

wherein the light emitting layer composed of a single layer or a plurality of layers is formed on the GaP substrate through direct bonding,

a first electrode is provided on the other face of the GaP substrate; and

a second electrode is provided so as to be connected to the translucent electrode layer.

The semiconductor light emitting device of the present invention comprises a translucent electrode layer and a GaP substrate disposed above and below the light emitting layer respectively, both of which are transparent to the wavelength of emitted light from the light emitting layer, which makes it possible to extract light from the upper face and side faces of the device, resulting in increased light extraction efficiency compared to the case of using a substrate opaque to the wavelength of emitted light. Moreover, when a current is passed between the first electrode and the second electrode in operation of the device, the passing current is diffused by the translucent electrode layer, and evenly injected into the light emitting layer. Consequently, the internal quantum efficiency is increased. As a result, the property of the semiconductor light emitting device is improved and high luminance is implemented. In the semiconductor light emitting device of the present invention, the translucent electrode layer diffuses the current, so that it is not necessary to provide a several dozen μm thick current diffusion layer containing p-type dopants in the vicinity of the light emitting layer as seen in the conventional example, and therefore diffusion of the p-type dopants into the light emitting layer is restrained. Also, the absence of the current diffusion layer may reduce the thickness of epitaxially grown layers. Therefore, it becomes possible to decrease maintenance frequency of the growth equipment, resulting in increased productivity as well as enhanced safety.

Also in one embodiment, the semiconductor light emitting device further comprises a GaP layer disposed between the GaP substrate and the light emitting layer composed of a single layer or a plurality of layers, the GaP layer being in contact with the GaP substrate.

The semiconductor light emitting device in this one embodiment comprises a GaP layer disposed between the GaP substrate and the light emitting layer composed of a single layer or a plurality of layers, the GaP layer being in contact with the GaP substrate, which prevents occurrence of VF (Forward Voltage) rise due to heterojunction between the GaP layer and the GaP substrate.

The light emitting layer is preferably composed of (Al_{y}Ga_{1-y})_{z}In_{1-z}P layer (where 0≦y≦1, 0≦z≦1). If the light emitting layer is composed of (Al_{y}Ga_{1-y})_{z}In_{1-z}P layer, an emitted light wavelength of 550 nm to 670 nm is obtained.

The translucent electrode layer is preferably composed of at least one of indium oxide, tin oxide, indium tin oxide, zinc oxide, and magnesium oxide. If the translucent electrode layer is composed of at least one of indium oxide, tin oxide, indium tin oxide, zinc oxide, and magnesium oxide, it becomes possible to obtain 90% or more transmittance of visible light. Therefore, it further ensures implementation of high luminance.

According to the semiconductor light emitting device and the method for manufacturing the same in the present invention as shown in the above description, it becomes possible to restrain diffusion of p-type dopants into the light emitting layer (or the active layer), which implements high luminance as well as decreases maintenance frequency of growth equipment.

### BRIEF DESCRIPTION OF THE DRAWINGS

FIGS. 1A, 1B, and 1C are respectively a side view, a top view, and a bottom view showing a semiconductor light emitting device in a first embodiment of the present invention;

FIG. 2 is a side view showing a manufacturing step of the semiconductor light emitting device of FIG. 1;

FIG. 3 is a side view showing a manufacturing step of the semiconductor light emitting device of FIG. 1;

FIG. 4 is a side view showing a manufacturing step of the semiconductor light emitting device of FIG. 1;

FIG. 5 is a view showing the dependence of external quantum efficiency on the thickness of a contact layer;

FIGS. 6A, 6B, and 6C are respectively a side view, a top view, and a bottom view showing a semiconductor light emitting device in a second embodiment of the present invention;

FIG. 7 is a side view showing a manufacturing step of the semiconductor light emitting device of FIG. 6;

FIG. 8 is a side view showing a manufacturing step of the semiconductor light emitting device of FIG. 6;

FIG. 9 is a side view showing a manufacturing step of the semiconductor light emitting device of FIG. 6;

FIGS. 10A and 10B are cross sectional views showing manufacturing steps of a first conventional semiconductor light emitting device;

FIGS. 11A, 11B, and 11C are cross sectional views showing manufacturing steps of a second conventional semiconductor light emitting device; and

FIGS. 12A, 12B, and 12C are cross sectional views showing manufacturing steps of a third conventional semiconductor light emitting device.

### DETAILED DESCRIPTION OF THE PREFERRED EMBODIMENTS

Embodiments of the invention will now be described with reference to the accompanying drawings.

(First Embodiment)

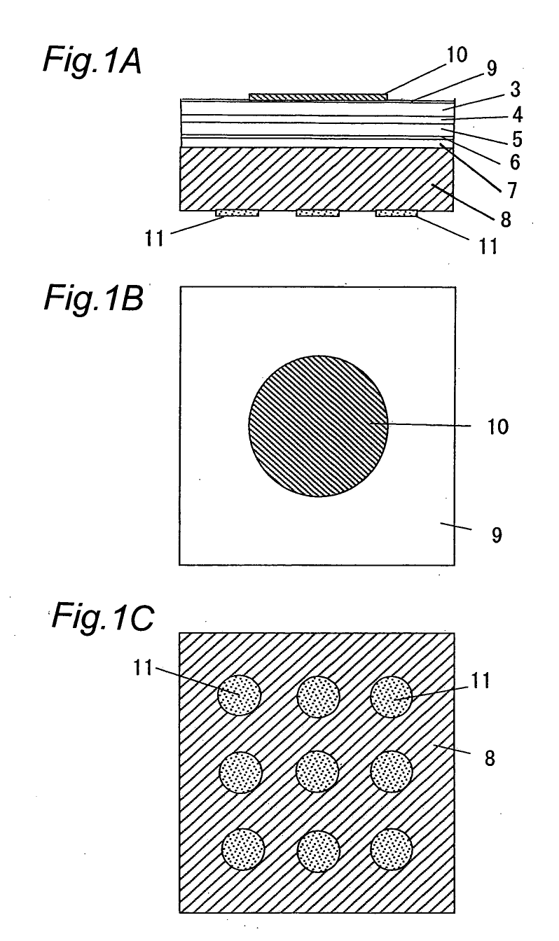

FIG. 1A is a side view showing a semiconductor light emitting device in a first embodiment, FIG. 1B is a top view of the semiconductor light emitting device, and FIG. 1C is a bottom view of the semiconductor light emitting device.

As shown in FIG. 1A, the semiconductor light emitting device is composed of an n-type GaP substrate 8, on one face (top face in FIG. 1A) of which there are disposed, in a bottom-up order, an n-type GaP cap layer (with a thickness of 1 μm) 7, an n-type (Al_{0.2}Ga_{0.8})_{0.77}In_{0.23}P intermediate layer (with a thickness of 0.15 μm) 6, an n-type (Al_{0.7}Ga_{0.3})_{0.5}In_{0.5}P cladding layer (with a thickness of 1 μm) 5, a p-type quantum well active layer 4 as a light emitting layer, a p-type (Al_{0.7}Ga_{0.3})_{0.5}In_{0.5}P cladding layer (with a thickness of 1 μm) 3, and a translucent electrode layer 9 made of zinc oxide. Further, n-type electrodes 11 made of AuSi are provided as a first electrode on the other face (bottom face in FIG. 1A) of the GaP substrate 8, while a bonding pad 10 made of Au is provided as a second electrode on the surface (top face in FIG. 1A) of the translucent electrode layer 9.

As shown in FIG. 1C, the n-type electrodes 11 are each processed into a pattern of a relatively small circle having a diameter of 30 μm, and the plurality of the circles (total 9 circles placed in 3 rows and 3 columns in this example) are disposed in a matrix shape on the bottom face. As shown in FIG. 1B, the bonding pad 10 is processed into a pattern of a relatively large circle having a diameter of 120 μm, and that one circle is disposed in the middle of the top face.

The quantum well active layer 4, though not shown in detail, is structured such that a plurality of barrier layers made of (Al₀₅Ga_{0.5})_{0.5}In_{0.5}P and well layers made of GaInP are alternately laminated. Forming the quantum well active layer 4 from (Al_{y}Ga_{1-y})_{z}In_{1-y}P (where 0≦y≦1, 0≦z≦1) as a light emitting layer provides an emitted light wavelength of 550 nm to 670 nm.

The semiconductor light emitting device is manufactured in the following steps.

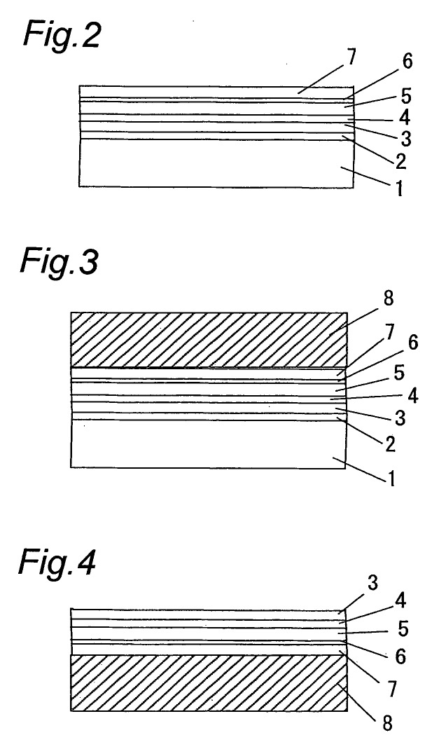

i) First, as shown in FIG. 2, on one face (top face in FIG. 2) of an n-type GaAs substrate 1 as a first semiconductor substrate, there are grown in sequence by MOCVD (Metal Organic Chemical Vapor Deposition) and laminated, a p-type GaAs buffer layer (with a thickness of 1 μm) 2, a p-type (Al_{0.7}Ga_{0.3})_{0.5}In_{0.5}P cladding layer (with a thickness of 1 μm) 3, a p-type quantum well active layer 4, an n-type (Al_{0.7}Ga_{0.3})_{0.5}In_{0.5}P cladding layer (with a thickness of 1 μm) 5, an n-type (Al_{0.2}Ga_{0.8})_{0.77}In_{0.23}P intermediate layer (with a thickness of 0.15 μm) 6, and an n-type GaP cap layer (with a thickness of 2 μm) 7. It is noted that the growth method may includes various methods such as MBE (Molecular Beam Epitaxy) method and MOMBE (Metal Organic Molecular Beam Epitaxy) method, in addition to the MOCVD method.

When the p-type (Al_{0.7}Ga_{0.3})_{0.5}In_{0.5}P cladding layer 3 is grown, a 0.1 μm thick portion of the cladding layer 3 that is in contact with the GaAs buffer layer 2 is set to have a carrier density of 2×10¹⁸cm⁻³, while a 0.9 μm thick portion of the cladding layer 3 that is in contact with the quantum well active layer 4 is set to have a carrier density of 5×10¹⁷ cm⁻³. Also, Zn is used as a p-type dopaht while Si is used as an n-type dopant.

ii) Next, after the surface of the substrate (wafer) in this state is mirror-finished through polishing, the surface is slightly etched with an etchant based on sulfuric acid and hydrogen peroxide. Also, an n-type GaP substrate 8 with a mirror-finished surface as a second substrate is prepared, and the surface of the GaP substrate 8 is also etched slightly with an etchant based on sulfuric acid and hydrogen peroxide. Then, after thoroughly washed with pure water and dried, these two substrates (wafers) are brought into close contact with each other as shown in FIG. 3, and heated in an atmosphere of hydrogen for one hour at a temperature of 800° C. By this, the surface (top face in FIG. 3) of the n-type GaP cap layer 7 on the GaAs substrate 1 and one face of the n-type GaP substrate 8, that is, two n-type GaP layers, are directly bonded.

Such direct bonding makes it possible to easily set the thickness of the n-type GaP substrate 8 to the level sufficient in terms of mechanical strength.

iii) Next, as shown in FIG. 4, the n-type GaAs substrate 1 and the p-type GaAs buffer layer 2 are etched away with use of an etchant based on ammonium and hydrogen peroxide. Then, the other face (bottom face in FIG. 4) of the n-type GaP substrate 8 is polished to obtain a target thickness.

iv) Next, as shown in FIG. 1A, a translucent electrode 9 made of zinc oxide is formed on the surface of the p-type (Al_{0.7}Ga_{0.3})_{0.5}In_{0.5}P cladding layer 3, further on top of which a bonding pad 10 made of Au is formed. Finally, on the bottom face of the n-type GaP substrate 8, nine circular n-type electrodes 11 made of AuSi are formed.

The external quantum efficiency of a thus-manufactured semiconductor light emitting device was evaluated under the condition that a current passed between the bonding pad 10 and the n-type electrode 11 was 20 mA, which was 11%. The external quantum efficiency of a conventionally structured semiconductor light emitting device having a p-type AlGaAs current diffusion layer with a thickness of 5 μm was approximately 7.8% under the same condition. The result proves that the semiconductor light emitting device in this embodiment has the external quantum efficiency improved about 1.5 times the external quantum efficiency of the conventional semiconductor light emitting device.

The improvement of the device property attributes to the use of the n-type GaAs substrate 1 and the n-type GaP substrate 8 instead a p-type substrate, and the absence of a p-type AlGaAs current diffusion layer with Zn dopes in the semiconductor light emitting device of this embodiment. More specifically, diffusion of Zn, a p-type dopant, into the light emitting layer 4 during epitaxial growing operation and direct bonding operation that involves high temperature is minimized and so is the resultant deterioration of internal quantum efficiency. Moreover, since the translucent electrode layer 9 contributes to diffusion of a passing current, the current is evenly injected into the light emitting layer, leading to increased internal quantum efficiency.

Furthermore, the semiconductor light emitting device is composed of the translucent electrode layer 9 and the GaP substrate 8 disposed above and below the light emitting layer 4 respectively, both of which are transparent to the wavelength of emitted light from the light emitting layer 4. This makes it possible to extract light from the upper face and side faces of the device, which increases light extraction efficiency compared to the case of using a substrate opaque to the wavelength of emitted light. Also, the GaP cap layer 7 is in contact with the GaP substrate 8, which prevents occurrence of VF (Forward Voltage) rise due to heterojunction between the GaP layer and the GaP substrate.

As a result, the property of the semiconductor light emitting device is improved and high luminance is achieved.

Further, an operating voltage of the semiconductor light emitting device in this embodiment was 2.3V with a passing current of 20 mA. Providing a p-type Al_{0.5}Ga_{0.5}As layer (p-type contact layer) with a carrier density of 5×10¹⁸cm⁻³ and a thickness of 0.2 μm in between the translucent electrode layer 9 and the p-type (Al_{0.7}Ga_{0.3})_{0.5}In_{0.5}P cladding layer 3 makes it possible to lower the operating voltage up to 2.1V with the luminance of the semiconductor light emitting device being maintained.

This is because the p-type contact layer having a carrier density of 5×10¹⁸cm⁻³ or more makes it possible to decrease voltage drop on a interface between the translucent electrode layer and the p-type contact layer during operation of the device.

The above-stated p-type contact layer is an AlₓGa₁₋ₓAs (where 0.5≦×≦0.7) layer transparent to the wavelength of emitted light from the light emitting layer, so that the light extraction efficiency is not decreased.

Further, by setting the carrier density of the p-type contact layer to 1×10⁹cm⁻³ or less, more preferably 5×10 ¹⁸cm⁻³, and limiting the thickness of the p-type semiconductor layer to be within a specified value, the total volume of p-type dopants is restricted, which makes it possible to restrain the p-type dopants from diffusing into the light emitting layer during high-temperature treatment. Therefore, depression of the internal quantum efficiency may be inhibited. Consequently, degradation of the internal quantum efficiency may be restrained. As a result, decrease in external quantum efficiency (luminance) of the semiconductor light emitting device may be prevented.

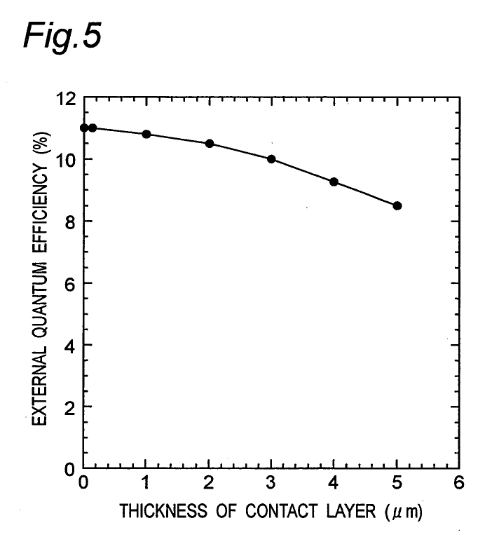

More particularly, as shown in FIG. 5, setting the thickness of the p-type contact layer to 3 μm or less makes it possible to limit decrease in external quantum efficiency (luminance) of the semiconductor light emitting device within 10%.

It is noted that provision of the p-type contact layer may be achieved by forming the p-type contact layer between the p-type GaAs buffer layer 2 and the p-type (Al_{0.7}Ga_{0.3})_{0.5}In_{0.5}P cladding layer 3 in the initial growing step by MOCVD method.

In this embodiment, the p-type current diffusion layer is not provided, which may reduce the thickness of epitaxially grown layers by half the thickness of the conventionally structured semiconductor light emitting device having a p-type AlGaAs current diffusion layer with a thickness of 5 μm. Therefore, it becomes possible to decrease maintenance frequency of the growth equipment by half, resulting in increased productivity as well as enhanced safety.

(Second Embodiment)

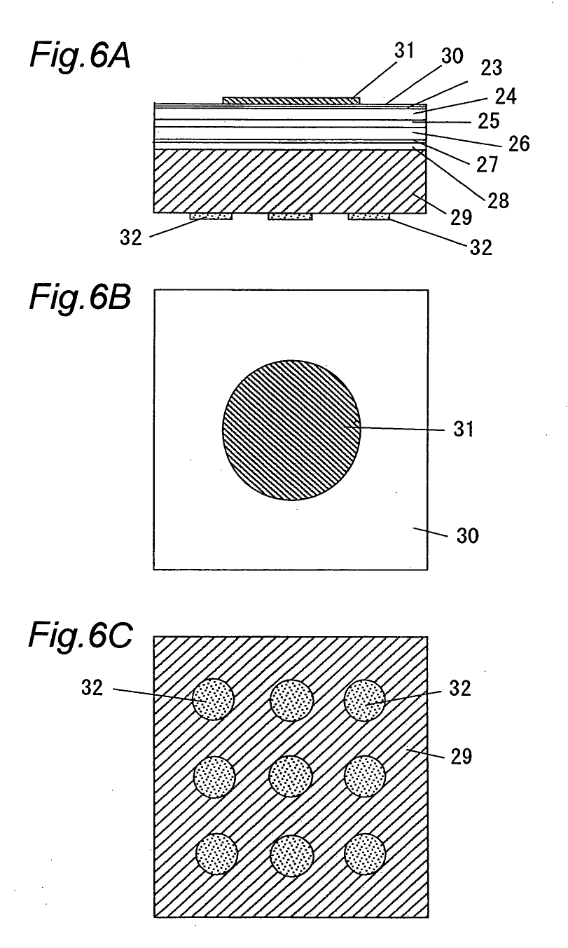

FIG. 6A is a side view showing a semiconductor light emitting device in a second embodiment, FIG. 6B is a top view of the semiconductor light emitting device, and FIG. 6C is a bottom view of the semiconductor light emitting device.

As shown in FIG. 6A, the semiconductor light emitting device is composed of an n-type GaP substrate 29, on one face (top face in FIG. 6A) of which there are disposed, in a bottom-up order, an n-type GaP cap layer (with a thickness of 1 μm) 28, an n-type (Al_{0.2}Ga_{0.8})_{0.77}In_{0.23}P intermediate layer (with a thickness of 0.15 μm) 27, an n-type Al_{0.5}In_{0.5}P cladding layer (with a thickness of 1 μm) 26, a p-type quantum well active layer 25 as a light emitting layer, a p-type Al_{0.5}In_{0.5}P cladding layer (with a thickness of 1 μm) 24, a p-type (Al_{0.5}Ga_{0.5})_{0.5}In_{0.5}P contact layer (with a thickness of 0.2 μm) 23, and a translucent electrode layer 30 made of zinc oxide. Further, n-type electrodes 32 made of AuSi are provided as a first electrode on the other face (bottom face in FIG. 6A) of the GaP substrate 29, while a bonding pad 31 made of Au is provided as a second electrode on the surface (top face in FIG. 6A) of the translucent electrode layer 30.

As shown in FIG. 6C, the n-type electrodes 32 are each processed into a pattern of a relatively small circle having a diameter of 30 μm, and the plurality of the circles (total 9 circles placed in 3 rows and 3 columns in this example) are disposed in a matrix shape on the bottom face. As shown in FIG. 6B, the bonding pad 31 is processed into a pattern of a relatively large circle having a diameter of 120 μm, and this one circle is disposed in the middle of the top face.

The quantum well active layer 25, though not shown in detail, is structured such that a plurality of barrier layers made of (Al_{0.7}Ga_{0.3})_{0.5}In_{0.5}P and well layers made of (Al_{0.3}Ga_{0.7})_{0.5}In_{0.5}P are alternately laminated. Forming the quantum well active layer 25 from (Al_{y}Ga_{1-y})_{z}In_{1-z}P (where 0≦y≦1, 0≦z≦1) as a light emitting layer provides an emitted light wavelength of 550 nm to 670 nm.

The semiconductor light emitting device is manufactured in the following steps.

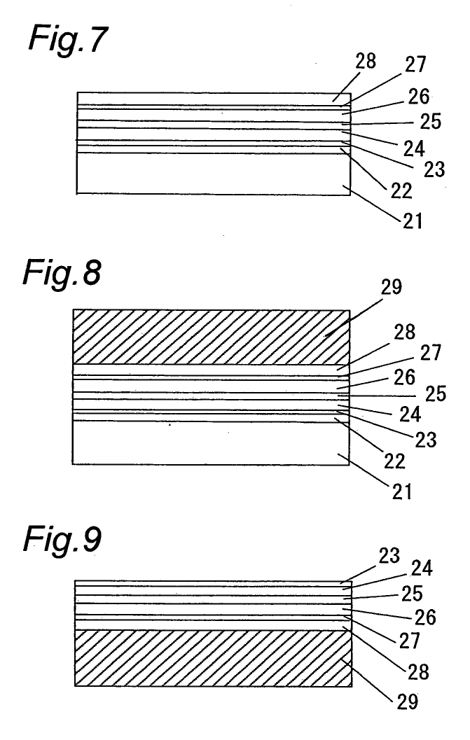

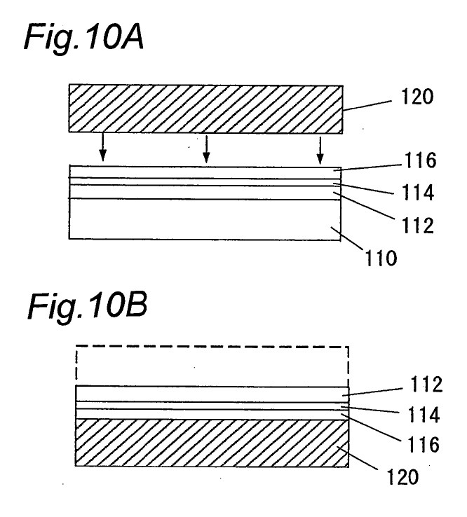

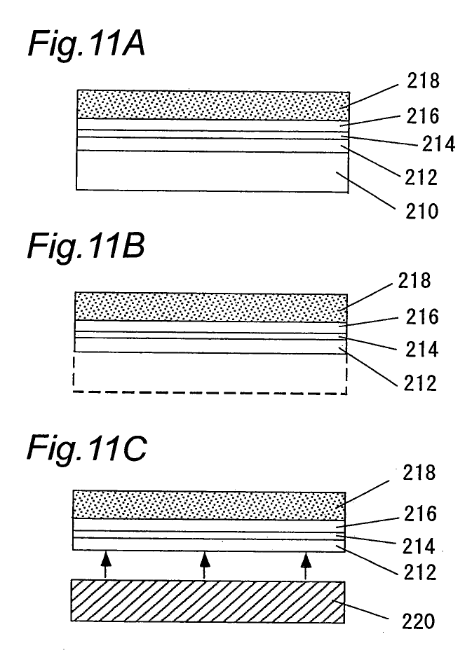

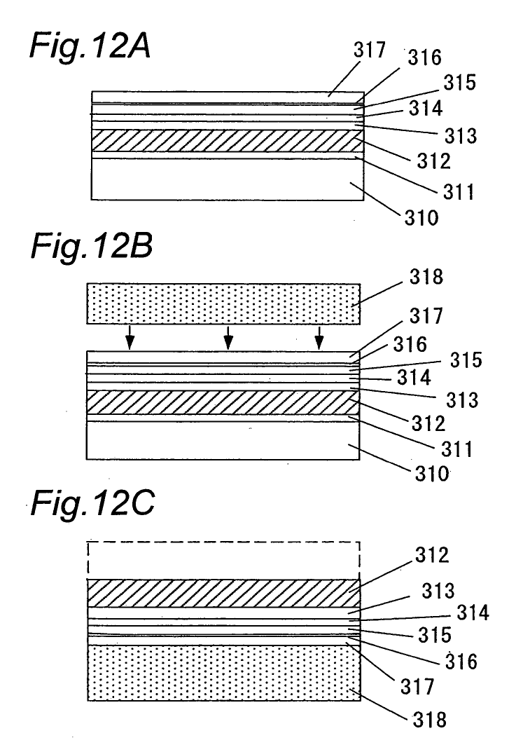

i) First, as shown in FIG. 7, on one face (top face in FIG. 7) of an n-type GaAs substrate 21 as a first semiconductor substrate, there are grown in sequence by MOCVD (Metal Organic Chemical Vapor Deposition) method and laminated, a p-type GaAs buffer layer (with a thickness of 1 μm) 22, a p-type (Al_{0.5}Ga_{0.5})_{0.5}In_{0.5}P contact layer (with a thickness of 0.2 μm) 23, a p-type Al_{0.5}In_{0.5}P cladding layer (with a thickness of 1 μm) 24, a p-type quantum well active layer 25, an n-type Al_{0.5}In_{0.5}P cladding layer (with a thickness of 1 μm) 26, an n-type (Al_{0.2}Ga_{0.8})_{0.77}In_{0.23}P intermediate layer (with a thickness of 0.15 μm) 27, and an n-type GaP cap layer (with a thickness of 1 μm) 28.

ii) Next, on top of the above, as shown in FIG. 8, an n-type GaP layer (hereinafter referred to as “GaP substrate”) 29 as a second semiconductor substrate is epitaxially grown by VPE method to reach a target thickness sufficient in terms of mechanical strength, that is approximately 100 μm in this example.

iii) Next, as shown in FIG. 9, the n-type GaAs substrate 21 and the p-type GaAs buffer layer 22 are etched away with use of an etchant based on ammonium and hydrogen peroxide.

It is noted that the n-type GaP substrate 29 is grown to a target thickness by VPE method, which eliminates the necessity of polishing or the like in this stage for adjusting the thickness of the n-type GaP substrate 29. Therefore, compared to the case of forming the GaP substrate 29 through direct bonding, the manufacturing step may be simplified.

iv) Next, as shown in FIG. 6A, a translucent electrode 30 made of zinc oxide is formed on the surface of the p-type (Al_{0.5}Ga_{0.5})_{0.5}In_{0.5}P contact layer 23, further on top of which a bonding pad 31 made of Au is formed. Finally, on the bottom face of the n-type GaP substrate 29, nine circular n-type electrodes 32 made of AuSi are formed.

The external quantum efficiency of a thus-manufactured semiconductor light emitting device was evaluated under the condition that a current passed between the bonding pad 31 and the n-type electrode 32 was 20 mA, which was 4.2%. The external quantum efficiency of a conventionally structured semiconductor light emitting device having a p-type AlGaAs current diffusion layer with a thickness of 5 μm was approximately 3.0% under the same condition. The result proves that the semiconductor light emitting device in this embodiment has the external quantum efficiency improved about 1.4 times the external quantum efficiency of the conventional semiconductor light emitting device.

Although the p-type (Al_{0.5}Ga_{0.5})_{0.5}In_{0.5}P layer is used as a contact layer in this embodiment, those composed with smaller mixed crystal ratio of Al such as Ga_{0.5}In_{0.5}P may be adopted as a contact layer if their light absorption at the wavelength of emitted light is small enough. With the smaller mixed crystal ratio of Al, the surface becomes resistant to oxidizing, thereby providing higher doping concentration. In such a case, it becomes possible to decrease voltage drop on a interface between the translucent electrode layer and the p-type semiconductor layer, thereby achieving an increased yield of the device. Moreover, as with the first embodiment, the GaP cap layer 28 is in contact with the GaP substrate 29, which prevents occurrence of VF (Forward Voltage) rise due to heterojunction between the GaP layer and the GaP substrate.

Although the n-type GaAs substrate with Si dopes is used as a first semiconductor substrate in the above-described embodiments, the present invention is not limited thereto. The GaAs substrate of a nondope type or a weak p-type in which the diffusion of dopants into the light emitting layer is substantially negligible may bring about the same effect. In order for a GaAs substrate to come under the “weak p-type GaAs substrate” that makes diffusion into the light emitting layer substantially negligible, it is enough for the p-type carrier density in the GaAs substrate to be set to, e.g., 1×10¹⁸cm⁻³ or less, preferably 5×10¹⁷cm⁻³ or less, and more preferably 1×10¹⁷cm⁻³ or less, although it may depend on coming thermal history. With the thermal history stated in each embodiment, if the p-type carrier density in the GaAs substrate is around 5×10¹⁷cm⁻³ or less, diffusion into the light emitting layer is determined to be sufficiently small. If the first semiconductor substrate is a GaAs substrate, it becomes possible to manufacture a high luminance semiconductor light emitting device having a semiconductor layer made of materials that lattice-match with the GaAs substrate.

Without being. limited to zinc oxide, materials of the translucent electrode layer may include indium oxide, tin oxide, indium tin oxide, and magnesium oxide. If the translucent electrode layer is composed of at least one of indium oxide, tin oxide, indium tin oxide, zinc oxide, and magnesium oxide, it becomes possible to obtain 90% or more transmittance of visible light. Therefore, it further ensures implementation of high luminance.

The invention being thus described, it will be obvious that the same may be varied in many ways. Such variations are not be regarded as a departure from the spirit and scope of the invention, and all such modifications as would be obvious to one skilled in the art are intended to be included within the scope of the following claims.

What is claimed is:

1. A method for manufacturing a semiconductor light emitting device, comprising:
laminating a light emitting layer on a nondope type, weak p-type, or n-type first semiconductor substrate, the light emitting layer being composed of a single or a plurality of semiconductor layers;
laminating an n-type semiconductor layer on the light emitting layer, the n-type semiconductor layer being composed of a single or a plurality of layers;
forming a second semiconductor substrate on an surface of the n-type semiconductor layer, the second semiconductor substrate being transparent to a wavelength of emitted light from the light emitting layer;
then removing the first semiconductor substrate; and
forming a translucent electrode layer on a plane exposed by removing of the first semiconductor substrate, the translucent electrode layer being transparent to the wavelength of emitted light from the light emitting layer.

2. The method for manufacturing the semiconductor light emitting device as claimed in claim 1, further comprising, before laminating the light emitting layer on the first semiconductor substrate, forming a p-type semiconductor layer on the first semiconductor substrate, wherein the p-type semiconductor layer is composed of a single layer or a plurality of layers whose composition is different from that of the first semiconductor substrate.

3. The method for manufacturing the semiconductor light emitting device as claimed in claim 1, wherein the second semiconductor substrate is formed through direct bonding.

4. The method for manufacturing the semiconductor light emitting device as claimed in claim 1, wherein the second semiconductor substrate is formed through epitaxial growing.

5. The method for manufacturing the semiconductor light emitting device as claimed in claim 2, wherein the second semiconductor substrate is formed through direct bonding.

6. The method for manufacturing the semiconductor light emitting device as claimed in claim 2, wherein the second semiconductor substrate is formed through epitaxial growing.

7. The method for manufacturing the semiconductor light emitting device as claimed in claim 2, wherein the p-type semiconductor layer has a carrier density of 1×10¹⁸cm⁻³ or more and 1×10¹⁹cm⁻³ or less, and contains an AlₓGa₁₋ₓAs layer (where 0.5×≦×≦0.7) that is transparent to the wavelength of emitted light from the light emitting layer.

8. The method for manufacturing the semiconductor light emitting device as claimed in claim 2,
wherein the p-type semiconductor layer has a carrier density of 1×10¹⁸cm⁻³ or more and 1×10¹⁹cm⁻³ or less, and contains an (Al_{y}Ga_{1-y})_{z}In_{1-z}P layer (where 0≦y≦1, 0≦z≦1) that is transparent to the wavelength of emitted light from the light emitting layer.

9. The method for manufacturing the semiconductor light emitting device as claimed in claim 2,
wherein the p-type semiconductor layer has a thickness of 3 μm or less.

10. A semiconductor light emitting device, comprising
a light emitting layer composed of a single layer or a plurality of layers and a translucent electrode layer laminated in this order on one face of a GaP substrate, the GaP substrate and the translucent electrode layer being transparent to a wavelength of emitted light from the light emitting layer,
wherein the light emitting layer composed of a single layer or a plurality of layers is formed on the GaP substrate through direct bonding,
a first electrode is provided on the other face of the GaP substrate; and
a second electrode is provided so as to be connected to the translucent electrode layer.

11. The semiconductor light emitting device as claimed in claim 10, further comprising a GaP layer disposed between the GaP substrate and the light emitting layer composed of a single layer or a plurality of layers, the GaP layer being in contact with the GaP substrate.
